(19) United States
(12) Patent Application Publication
(10) Pub. No.: US 2026/0285884 A1
(43) Pub. Date: Sep. 24, 2026

(54) CHLOROSILYL-SUBSTITUTED SILACYCLOALKANES AND THEIR USE FOR FORMATION OF FILMS COMPRISING SILICON AND OXYGEN

(71) Applicant: VERSUM MATERIALS US, LLC, TEMPE, AZ (US)

(72) Inventors: HARIPIN CHANDRA, SAN MARCOS, CA (US); MATTHEW R. MACDONALD, SANTA MARGARITA, CA (US); XINJIAN LEI, VISTA, CA (US); MANCHAO XIAO, SAN DIEGO, CA (US); PEGAH BAGHERI, VISTA, CA (US); MAHSA KONH, CARLSBAD, CA (US); XUEZHONG JIANG, SAN MARCOS, CA (US); MING LI, SAN MARCOS, CA (US)

(21) Appl. No.: 19/477,457

(22) PCT Filed: Apr. 23, 2024
(86) PCT No.: PCT/US2024/025884

§ 371 Date: Oct. 21, 2025

Related U.S. Application Data
(60) Provisional application No. 63/498,134, filed on Apr. 25, 2023.

(51) Int. Cl. C07F 7/12; C09D 1/00

(52) U.S. Cl. CPC C07F 7/12; C09D 1/00

(57) ABSTRACT

A halidosilyl-substituted cyclic silicon precursor compound has at least 2 to 1 of carbon to silicon ratio and is defined by Formula I herein. A method for forming a film comprising silicon and oxygen and having a carbon content ranging from 10 at. % to 50 at. % via a thermal ALD process includes placing one or more substrates comprising a surface feature into a reactor; heating to reactor to one or more temperatures ranging from ambient temperature to about 600° C. and optionally maintaining the reactor at a pressure of 100 torr or less; introducing into the reactor at least one silicon precursor according to Formula I; purging with an inert gas; providing a nitrogen source into the reactor to react with the surface to form a carbon doped silicon nitride film, purging with inert gas to remove reaction by-products, repeating steps to provide a desired thickness of the carbon doped silicon nitride film, treating the resulting carbon doped silicon nitride film with an oxygen source at one or more temperatures ranging from about ambient temperature to 1000° C. or from about 100° C. to 400° C. to convert the carbon doped silicon nitride film into a carbon doped silicon oxide film; and exposing the carbon doped silicon oxide film to a plasma comprising hydrogen.

### CROSS-REFERENCE TO RELATED APPLICATIONS

This application claims the benefit of U.S. provisional patent application Ser. No. 63/498,134, filed Apr. 25, 2023. The entire content of the identified provisional patent is hereby fully incorporated herein by reference.

### FIELD OF THE INVENTION

Described herein are compounds, compositions containing such, and methods using such for the fabrication of an electronic device. More specifically, described herein are compounds, and compositions and methods incorporating such, for the deposition of a dielectric constant (<6.0) and low leakage current density silicon-containing film with high carbon content such as, without limitation, a carbon doped silicon oxide, a carbon doped silicon nitride, and a carbon doped silicon oxynitride film.

### BACKGROUND OF THE INVENTION

For low-k spacer applications, carbon doped silicon-containing films such as silicon oxide films are needed to achieve a low dielectric constant (k-value). Higher carbon content in such films allows increased tunability. On the other hand, nitrogen content in the films is crucial for device integrations since films with some nitrogen content are more resistant to high temperatures and oxygen ashing. Further, films with higher nitrogen content generally have higher k-values than those having a lower nitrogen content. Therefore, there is balance for the amounts of nitrogen and carbon in carbon doped silicon-containing films to meet both electrical and integration steps requirements. There is a need in the art to provide a composition and method using such for depositing high carbon content (e.g., a carbon content of about 10 atomic % or greater as measured by X-ray photoelectron spectroscopy (XPS)) silicon-containing films, including carbon doped silicon oxide films, for many applications within the electronics industry.

US Publ. No. 2018/0033614 discloses silicon precursors and methods incorporating such that have one or two Si—C—Si linkages for deposition of low k carbon doped silicon-containing films using atomic layer deposition that may include a plasma.

U.S. Pat. No. 8,575,033 describes methods for deposition of silicon carbide films on a substrate surface. The methods include the use of vapor phase carbosilane precursors and may employ plasma enhanced atomic layer deposition processes.

US Publ. No. 2013/022496 teaches a method of forming a dielectric film having Si—C bonds on a semiconductor substrate by atomic layer deposition (ALD), includes: (i) adsorbing a precursor on a surface of a substrate; (ii) reacting the adsorbed precursor and a reactant gas on the surface; and (iii) repeating steps (i) and (ii) to form a dielectric film having at least Si—C bonds on the substrate.

PCT Appl. No. WO14134476A1 describes methods for the deposition of films comprising SiCN and SIOCN. Certain methods involve exposing a substrate surface to a first and second precursor, the first precursor having a formula (X_{y}H_{3-y}Si)zCH_{4-z}, (X_{y}H_{3-y}Si)(CH₂)(SiXₚH₂₋ₚ)(CH₂)(SiX_{y}H_{3-y}), or (X_{y}H_{3-y}Si)(CH₂)ₙ(SiX_{y}H_{3-y}), wherein X is a halogen, y has a value of between 1 and 3, and z has a value of between 1 and 3, p has a value of between 0 and 2, and n has a value between 2 and 5, and the second precursor comprising a reducing amine. Certain methods also comprise exposure of the substrate surface to an oxygen source to provide a film comprising carbon doped silicon oxide.

Hirose, Y., Mizuno, K., Mizuno, N., Okubo, S., Okubo, S., Yanagida, K. and Yanagita, K. (2014)) “method of manufacturing semiconductor device, substrate processing apparatus, and recording medium” US Appl.No. 2014287596A describes a method of manufacturing a semiconductor device including forming a thin film containing silicon, oxygen and carbon on a substrate by performing a cycle a predetermined number of times, the cycle including: supplying a precursor gas containing silicon, carbon and a halogen element and having an Si—C bonding, and a first catalytic gas to the substrate; and supplying an oxidizing gas and a second catalytic gas to the substrate.

Hirose, Y., Mizuno, N., Yanagita, K. and Okubo, S. (2014)) “Method of manufacturing semiconductor device, substrate processing apparatus, and recording medium.” U.S. Pat. No. 9,343,290 B describes a method of manufacturing a semiconductor device includes forming an oxide film on a substrate by performing a cycle a predetermined number of times. The cycle includes supplying a precursor gas to the substrate; and supplying an ozone gas to the substrate. In the act of supplying the precursor gas, the precursor gas is supplied to the substrate in a state where a catalytic gas is not supplied to the substrate, and in the act of supplying the ozone gas, the ozone gas is supplied to the substrate in a state where an amine-based catalytic gas is supplied to the substrate.

U.S. Pat. No. 9,349,586 B discloses a thin film having a desirable etching resistance and a low dielectric constant.

US Publ. No. 2015/0044881A describes a method to form a film containing carbon added at a high concentration is formed with high controllability. A method of manufacturing a semiconductor device includes forming a film containing silicon, carbon and a predetermined element on a substrate by performing a cycle a predetermined number of times. The predetermined element is one of nitrogen and oxygen. The cycle includes supplying a precursor gas containing at least two silicon atoms per one mol., carbon and a halogen element and having a Si—C bonding to the substrate, and supplying a modifying gas containing the predetermined element to the substrate.

The reference entitled “Highly Stable Ultrathin Carbosiloxane Films by Molecular Layer Deposition”, Han, Z. et al., Journal of Physical Chemistry C, 2013, 117, 19967 teaches growing carbosiloxane film using 1,2-bis[(dimethylamino)dimethylsilyl]ethane and ozone. Thermal stability shows film is stable up to 40° C. with little thickness loss at 60° C.

Liu et al, Jpn. J. Appl. Phys., 1999, Vol. 38, 3482-3486, teaches H₂ plasma use on polysilsesquioxane deposited with spin-on technology. The H₂ plasma provides stable dielectric constant and improves film thermal stability and O₂ ash (plasma) treatment

Kim et al, Journal of the Korean Physical Society, 2002, Vol. 40, 94, teaches H₂ plasma treatment on PECVD carbon doped silicon oxide film improves leakage current density (4-5 orders of magnitude) while dielectric constant increases from 2.2 to 2.5. The carbon doped silicon oxide film after H₂ plasma has less damage to during oxygen ashing process.

Posseme et al, Solid State Phenomena, 2005, Vol. 103-104, 337, teaches different H₂/inert plasma treatment on carbon doped silicon oxide PECVD film. The k is not improving after H₂ plasma treatment suggesting no bulk modification.

The disclosure of the previously identified patents, patent applications and publications is hereby incorporated by reference.

### BRIEF SUMMARY OF THE INVENTION

The composition and method described herein overcome the problems of the prior art by providing a composition or formulation for depositing a conformal silicon-containing film using thermal atomic layer deposition (ALD). In one aspect, the composition for depositing a silicon-containing film comprises: (a) at least one halidosilyl-substituted cyclic silicon precursor according to Formula I:

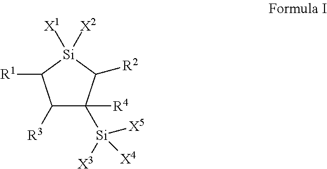

wherein R¹⁻⁴ are each independently selected from the group consisting of hydrogen, linear or branched or cyclic C₁ to C₁₀ alkyl, and halide (i.e. F, Cl, Br and I), and wherein X¹⁻⁵ are independently selected from the group consisting of halide, hydrogen, and a C₁ to C₁₀ alkyl with a proviso that at least one X¹⁻⁵ are halide. Preferably R¹⁻⁴ are independently selected from the group consisting of hydrogen or methyl and X¹⁻⁵ are independently selected from the group consisting of hydrogen, methyl, Cl, Br or I.

In at least one aspect of the invention, the composition further includes (b) at least one solvent. In certain embodiments of the composition described herein, exemplary solvents can include, without limitation, ether, tertiary amine, alkyl hydrocarbon, aromatic hydrocarbon, siloxanes, tertiary aminoether, and combinations thereof. In certain embodiments, the difference between the boiling point of the precursor compound(s) and the boiling point of the solvent is 40° C. or less, less than about 30° C. and in some cases less than about 20° C., preferably less than 10° C.

Another aspect of the invention relates to a method for forming a carbon doped silicon oxide film having carbon content ranging from 10 at. % to 50 at. % via a thermal ALD process, the method comprising: a. placing one or more substrates comprising a surface feature into a reactor; b. heating to reactor to one or more temperatures ranging from ambient temperature to about 600° C. and optionally maintaining the reactor at a pressure of 100 torr or less; c. introducing into the reactor a precursor comprising at least one compound selected from a silicon precursor according to Formula 1; d. purging with an inert gas to remove any unreacted silicon precursor; e. providing a nitrogen source into the reactor to react with the surface to form a silicon carbonitride film; f. purging with inert gas to remove reaction by-products; g. repeating steps c to f to provide a desired thickness of silicon carbonitride film; h. treating the resulting silicon carbonitride film with an oxygen source at one or more temperatures ranging from about ambient temperature to 1000° C. or from about 100° to 400° C. to convert the carbon doped silicon nitride film into a carbon doped silicon oxide film; and i. exposing the carbon doped silicon oxide film to a plasma comprising hydrogen.

In another aspect, there is provided a method for depositing a film selected from a film comprising silicon and oxygen onto at least a surface of a substrate comprising the steps of placing the substrate into a reactor; heating the reactor to one or more temperatures ranging from about 25° C. to about 600° C.; introducing into the reactor a precursor comprising at least one compound selected from a silicon precursor according to Formula 1; introducing into the reactor a nitrogen source to react with at least a portion of the precursor to form a carbon doped silicon nitride film; and treating the carbon doped silicon nitride film with an oxygen source at one or more temperatures ranging from about 25° C. to 1000° C. or from about 100° to 400° C. under conditions sufficient to convert the carbon doped silicon nitride film into the carbon doped silicon oxynitride film. In certain embodiments, the carbon doped silicon oxide film or the carbon doped silicon oxynitride film has a carbon content of about 10 atomic weight percent (at. %) or greater as measured by XPS and an etch rate of at least 0.5 times less than thermal silicon oxide as measured in dilute hydrofluoric acid.

If desired, the invention further comprises treating the carbon doped silicon oxide or oxynitride film with a hydrogen plasma or a hydrogen/inert plasma at 25° C. to 600° C.

A further aspect of the invention relates to a film having a k of less than about 4, a carbon content of at least about 10 at. % or greater, based on XPS measurement and, in another aspect the inventive film can be formed according to any of the inventive methods.

Another aspect of the invention relates to stainless steel container housing the inventive compositions.

The embodiments of the invention may be used alone or in various combinations with each other.

### BRIEF DESCRIPTION OF THE DRAWINGS

None.

### DETAILED DESCRIPTION OF THE INVENTION

Described herein are silicon precursor compounds, and compositions and methods comprising same, to deposit a film comprising silicon and oxygen (e.g., having a carbon content of about 10 at. % or greater, preferably 15 at. % or greater, most preferably 20 at. % or greater as measured by XPS; a dielectric constant of 6.0 or less, preferably of 3.5 or less, most preferably 3.0 or less) via a deposition process such as, without limitation, a thermal atomic layer deposition process. Since the carbon content is an important factor for reducing the wet etch rate as well as increasing the ash resistance, the carbon content for this invention ranges from 10 at. % to 50 at. %, preferably 15 at. % to 40 at. %, and most preferably 20 at. % to 40 at. % as measured by XPS. The film deposited using the composition and method described herein exhibits an extremely low etch rate such as an etch rate of at least 0.5 times less than thermal silicon oxide as measured in dilute hydrofluoric acid (e.g., about 0.20 Å/s or less or about 0.15 Å/s or less in dilute HF (0.5 wt. %), or an etch rate of at least 0.1 times less than thermal silicon oxide, or an etch rate of at least 0.05 times less than thermal silicon oxide, or an etch rate of at least 0.01 times less than thermal silicon oxide while exhibiting variability in other tunable properties such as, without limitation, density, dielectric constant, refractive index, and elemental composition.

In certain embodiments, the silicon precursor precursors described herein, and methods using same, impart one or more of the herein-described features in the following manner. First, the as-deposited, reactive carbon-doped silicon-containing film is formed using at least one halidosilyl-substituted cyclic silicon precursor according to Formula 1:

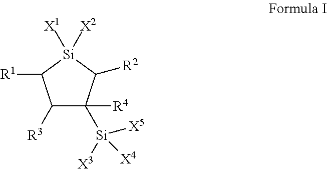

wherein R¹⁻⁴ are each independently selected from the group consisting of hydrogen, linear or branched or cyclic C₁ to C₁₀ alkyl, and halide (i.e. F, Cl, Br and I), and wherein X¹⁻⁵ are independently selected from the group consisting of halide, hydrogen, a C₁ to C₁₀ alkyl with a proviso that at least one X¹⁻⁵ are halide. Preferably R¹⁻⁴ are independently selected from the group consisting of hydrogen or methyl and X¹⁻⁵ are independently selected from the group consisting of hydrogen, methyl, Cl, Br or 1.

Without wishing to be bound by any theory or explanation, it is believed that some of the Si—C—C—Si linkages from the halidosilyl-substituted cyclic silicon precursor remains in the resulting as-deposited film and provides a high carbon content of at least 10 at. % to 50 at. %, preferably 15 at. % to 40 at. %, and most preferably 20 at. % to 40 at. % as measured by XPS.

Second, according to some embodiments, when exposing the as-deposited film to an oxygen source, such as water, either intermittently during the deposition process, as a post-deposition treatment, or a combination thereof, at least a portion or all of the nitrogen content in the film is converted to oxygen to provide a film selected from a carbon-doped silicon oxide or a carbon-doped silicon oxynitride film. The nitrogen in the as-deposited film is released as one or more nitrogen-containing by-products such as ammonia or an amine group.

In this or other embodiments, the final film is porous and has a density of about 1.7 grams/cubic centimeter (g/cc) or less and an etch rate of 0.20 Å/s or less in 0.5 wt. % dilute hydrogen fluoride.

In one aspect, the composition for depositing a silicon-containing film comprises at least one halidosilyl-substituted cyclic silicon precursor having at least 2 to 1 of carbon to silicon ratio according to Formula I:

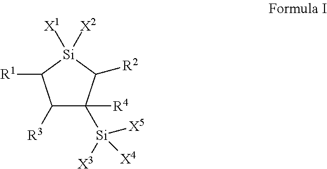

wherein R¹⁻⁴ are each independently selected from the group consisting of hydrogen, linear or branched or cyclic C₁ to C₁₀ alkyl, and halide (i.e. F, Cl, Br and I), and wherein X¹⁻⁵ are independently selected from the group consisting of halide, hydrogen, a C₁ to C₁₀ alkyl with a proviso that at least one X¹⁻⁵ are halide. Preferably R¹⁻⁴ are independently selected from the group consisting of hydrogen or methyl and X¹⁻⁵ are independently selected from the group consisting of hydrogen, methyl, Cl, Br or I. Exemplary compounds according to Formula I include but are not limited to those set forth in Table I:

TABLE I

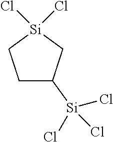 [SMILES: Cl[Si]1(Cl)CCC([Si](Cl)(Cl)Cl)C1]

1,1-dichloro-3-trichlorosilyl-1-
silacyclopentane

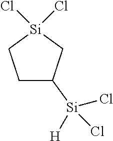

1,1-dichloro-3-dichlorosilyl-1-
silacyclopentane

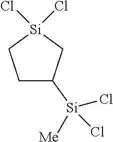 [SMILES: C[Si](Cl)(Cl)C1CC[Si](Cl)(Cl)C1]

1,1-dichloro-3-dichloromethylsilyl-1-
silacyclopentane

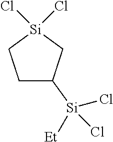 [SMILES: CC[Si](Cl)(Cl)C1CC[Si](Cl)(Cl)C1]

1,1-dichloro-3-dichloroethylsilyl-1-
silacyclopentane

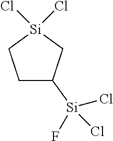 [SMILES: F[Si](Cl)(Cl)C1CC[Si](Cl)(Cl)C1]

1,1-dichloro-3-dichlorofluorosilyl-1-
silacyclopentane

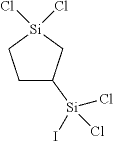 [SMILES: Cl[Si]1(Cl)CCC([Si](Cl)(Cl)I)C1]

1,1-dichloro-3-dichloroiodsilyl-1-
silacyclopentane

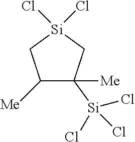 [SMILES: CC1C[Si](Cl)(Cl)CC1(C)[Si](Cl)(Cl)Cl]

1,1-dichloro-3,4-dimethyl-3-trichlorosilyl-
1-silacyclopentane

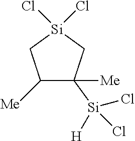 [SMILES: CC1C[Si](Cl)(Cl)CC1(C)[SiH](Cl)Cl]

1,1-dichloro-3,4-dimethyl-3-dichlorosilyl-
1-silacyclopentane

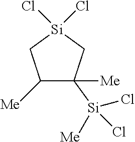 [SMILES: CC1C[Si](Cl)(Cl)CC1(C)[Si](C)(Cl)Cl]

1,1-dichloro-3,4-dimethyl-3-
dichloromethyl-silyl-1-silacyclopentane

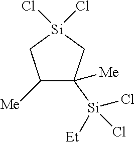 [SMILES: CC[Si](Cl)(Cl)C1(C)C[Si](Cl)(Cl)CC1C]

1,1-dichloro-3,4-dimethyl-3-
dichloroethyl-silyl-1-silacyclopentane

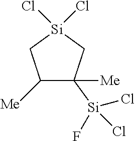 [SMILES: CC1C[Si](Cl)(Cl)CC1(C)[Si](F)(Cl)Cl]

1,1-dichloro-3,4-dimethyl-3-
dichlorofluoro-silyl-1-silacyclopentane

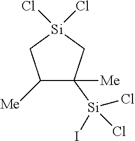 [SMILES: CC1C[Si](Cl)(Cl)CC1(C)[Si](Cl)(Cl)I]

1,1-dichloro-3,4-dimethyl-3-
dichloroiodo-silyl-1-silacyclopentane

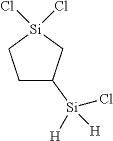

1,1-dichloro-3-chlorosilyl-1-
silacyclopentane

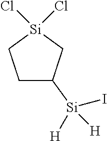

1,1-dichloro-3-iodosilyl-1-
silacyclopentane

According to a further embodiment, the composition further comprises (b) at least one solvent. In certain embodiments of the composition described herein, exemplary solvents can include, without limitation, ether, tertiary amine, alkyl hydrocarbon, aromatic hydrocarbon, tertiary aminoether, siloxanes, and combinations thereof. In certain embodiments, the difference between the boiling point of the compound having Si—C—C—Si linkages and the boiling point of the solvent is 40° C. or less. The wt % of silicon precursor compound in the solvent can vary from 1 to 99 wt %, or 10 to 90 wt %, or 20 to 80 wt %, or 30 to 70 wt %, or 40 to 60 wt %, to 50 to 50 wt %. In some embodiments, the composition can be delivered via direct liquid injection into a reactor chamber for silicon-containing film using conventional direct liquid injection equipment and methods.

Another embodiment of the method described herein includes depositing a film comprising silicon and oxygen having a carbon content ranging from 10 at. % to 50 at. %, preferably 15 at. % to 40 at. %, using a thermal ALD process. In this embodiment, the method comprises:
a. placing one or more substrates comprising a surface feature into a reactor;
b. heating to reactor to one or more temperatures ranging from ambient temperature to about 600° C. and optionally maintaining the reactor at a pressure of 100 torr or less;
c. introducing into the reactor at least one silicon precursor according to Formula I;
d. purging with an inert gas thereby removing unreacted silicon precursor;
e. providing a nitrogen source into the reactor to react with the surface to form a carbon doped silicon nitride film;
f. purging with inert gas to remove reaction by-products;
g. repeating steps c to f to provide a desired thickness of carbon doped silicon nitride film;
h. treating the carbon doped silicon nitride film with an oxygen source at one or more temperatures ranging from about ambient temperature to 1000° C., preferably from about 100° to 400° C., to convert the carbon doped silicon nitride film into a carbon doped silicon oxide film, either in-situ or in another chamber;
i. exposing the carbon doped silicon oxide film to a plasma comprising hydrogen; and j. optionally treating the carbon doped silicon oxide film with a spike anneal at temperatures from 400 to 1000° C. or a UV light source. In this or other embodiments, the UV exposure step can be carried out either during film deposition, or once deposition has been completed.

In yet another embodiment of the method described herein includes depositing a film comprising silicon and oxygen having a carbon content ranging from 10 at. % to 50 at. %, preferably 15 at. % to 40 at. % using combination between thermal and plasma ALD. In this embodiment, the method comprises:
a. placing one or more substrates comprising a surface feature into a reactor;
b. heating the reactor to one or more temperatures ranging from ambient temperature to about 600° C., and optionally maintaining the reactor at a pressure of 100 torr or less;
c. introducing into the reactor at least one silicon precursor according to Formula I;
d. purging with an inert gas, thereby removing any unreacted silicon precursor;
e. providing a nitrogen source into the reactor to react with the surface to form a carbon doped silicon nitride film;
f. purging with an inert gas to remove reaction byproducts;
g. introducing oxygen source to form carbon doped silicon oxynitride;
h. purging with an inert gas to remove reaction byproducts;
i. optionally exposed film to a plasma source comprising hydrogen; and
j. purging with an inert gas to remove reaction byproducts
   Steps c-j are repeated multiple times in order to get a desired film thickness.

In one embodiment, the surface feature included with the substrate includes a pattern trench with aspect ratio of 1:9, opening of 180 nm.

In yet another further embodiment of the method described herein, a film comprising silicon and oxygen having a carbon content ranging from 10 at. % to 50 at. %, preferably 15 at. % to 40 at. % is deposited using a thermal ALD process with a catalyst comprising ammonia or an organic amine. In this embodiment, the method comprises:
a. placing one or more substrates comprising a surface feature into a reactor;
b. heating the reactor to one or more temperatures ranging from ambient temperature to about 150° C., and optionally maintaining the reactor at a pressure of 100 torr or less;
c. introducing into the reactor at least one silicon precursor according to Formula I;
d. purging with an inert gas, thereby removing any unreacted silicon precursor;
e. providing vapors of water into the reactor to react with the precursor, along with a catalyst, to form a carbon doped silicon oxide film;
f. purging with inert gas to remove any reaction by-products;
g. repeating steps c to f to provide a desired thickness of the carbon doped silicon oxide film;
h. exposing the carbon doped silicon oxide film to a plasma comprising hydrogen; and
i. optionally treating the carbon doped silicon oxide film with a spike anneal at temperatures from 400 to 1000° C. or with a UV light source. In this or other embodiments, the UV exposure step can be carried out either during film deposition, or once deposition has been completed.

In this or other embodiments, the catalyst is selected from a Lewis base such as pyridine, piperazine, ammonia, triethylamine or other organic amines. The amount of Lewis base vapors is at least one equivalent to the amount of the silicon precursor vapors produced in the reactor during step c.

In certain embodiments, the resulting carbon doped silicon oxide film is exposed to organoaminosilanes or chlorosilanes having Si-Me or Si—H or both to form a hydrophobic thin layer before exposing to hydrogen plasma treatment. Suitable organoaminosilanes include, but are not limited to, diethylaminotrimethylsilane, dimethylaminotrimethylsilane, ethylmethylaminotrimethylsilane, t-butylaminotrimethylsilane, iso-propylaminotrimethylsilane, di-isopropylaminotrimethylsilane, pyrrolidinotrimethylsilane, diethylaminodimethylsilane, dimethylaminodimethylsilane, ethylmethylaminodimethylsilane, t-butylaminodimethylsilane, iso-propylaminodimethylsilane, di-isopropylaminodimethylsilane, pyrrolidinodimethylsilane, bis(diethylamino)dimethylsilane, bis(dimethylamino)dimethylsilane, bis(ethylmethylamino)dimethylsilane, bis(di-isopropyllamino)dimethylsilane, bis(iso-propylamino)dimethylsilane, bis(tert-butylamino)dimethylsilane, dipyrrolidinodimethylsilane, bis(diethylamino)diethylsilane, bis(diethylamino)methylvinylsilane, bis(dimethylamino)methylvinylsilane bis(ethylmethylamino)methylvinylsilane, bis(di-isopropyllamino)methylvinylsilane, bis(iso-propylamino)methylvinylsilane, bis(tert-butylamino)methylvinylsilane, dipyrrolidinomethylvinylsilane, 2,6-dimethylpiperidinomethylsilane, 2,6-dimethylpiperidinodimethylsilane, 2,6-dimethylpiperidinotrimethylsilane, tris(dimethylamino)phenylsilane, tris(dimethylamino)methylsilane, di-iso-propylaminosilane, di-sec-butylaminosilane, chlorodimethylsilane, chlorotrimethylsilane, dichloromethylsilane, and dichlorodimethylsilane.

In another embodiments, the resulting carbon doped silicon oxide film is exposed to alkoxysilanes or cyclic alkoxysilanes having Si-Me or Si—H or both to form a hydrophobic thin layer before exposing to the hydrogen plasma treatment. Suitable alkoxysilanes or cyclic alkoxysilanes include, but are not limited to, diethoxymethylsilane, dimethoxymethylsilane, diethoxydmethylsilane, dimethoxydmethylsilane, 2,4,6,8-Tetramethylcyclotetrasiloxane, or octamethylcyclotetrasiloxane. Without wishing to be bound by any theory or explanation, it is believed that the thin layer formed by the organoaminosilanes or alkoxysilanes or cyclic alkoxysilanes may convert into dense carbon doped silicon oxide during plasma ashing process, further boosting the ashing resistance.

In another embodiment, a vessel for depositing a silicon-containing film comprising one or more silicon precursor compounds described herein. In one particular embodiment, the vessel comprises at least one pressurizable vessel (preferably of stainless steel having a design such as disclosed in U.S. Pat. Nos. U.S. Pat. Nos. 7,334,595; 6,077,356; 5,069,244; and 5,465,766 the disclosure of which is hereby incorporated by reference. The container can comprise either glass (borosilicate or quartz glass) or type 316, 316L, 304 or 304L stainless steel alloys (UNS designation S31600, S31603, S30400 S30403) fitted with the proper valves and fittings to allow the delivery of one or more precursors to the reactor for a CVD or an ALD process. In this or other embodiments, the silicon precursor is provided in a pressurizable vessel comprised of stainless steel and the purity of the precursor is 98% by weight or greater or 99.5% or greater which is suitable for the semiconductor applications. The silicon precursor compounds are preferably substantially free of metal ions such as, Al³⁺ ions, Fe²⁺, Fe³⁺, Ni²⁺, Cr³⁺. As used herein, the term “substantially free” as it relates to A³⁺ ions, Fe²⁺, Fe³⁺, Ni²⁺, Cr³⁺ means less than about 5 ppm (by weight), preferably less than about 3 ppm, and more preferably less than about 1 ppm, and most preferably about 0.1 ppm. In certain embodiments, such vessels can also have means for mixing the precursors with one or more additional precursor if desired. In these or other embodiments, the contents of the vessel(s) can be premixed with an additional precursor. Alternatively, the silicon precursor is and/or other precursor can be maintained in separate vessels or in a single vessel having separation means for maintaining the silicon precursor is and other precursor separate during storage.

The silicon-containing film is deposited upon at least a surface of a substrate such as a semiconductor substrate. In the method described herein, the substrate may be comprised of and/or coated with a variety of materials well known in the art including films of silicon such as crystalline silicon or amorphous silicon, silicon oxide, silicon nitride, amorphous carbon, silicon oxycarbide, silicon oxynitride, silicon carbide, germanium, germanium doped silicon, boron doped silicon, metal such as copper, tungsten, aluminum, cobalt, nickel, tantalum), metal nitride such as titanium nitride, tantalum nitride, metal oxide, group III/V metals or metalloids such as GaAs, InP, GaP and GaN, and a combination thereof. These coatings may completely coat the semi-conductor substrate, may be in multiple layers of various materials and may be partially etched to expose underlying layers of material. The surface may also have on it a photoresist material that has been exposed with a pattern and developed to partially coat the substrate. In certain embodiments, the semiconductor substrate comprising at least one surface feature selected from the group consisting of pores, vias, trenches, and combinations thereof. The potential application of the silicon-containing films include but not limited to low k spacer for FinFET or nanosheet, sacrificial hard mask for self aligned patterning process (such as SADP, SAQP, or SAOP).

The deposition methods used to form the silicon-containing films include, but are not limited to, an atomic layer deposition process, a cyclic chemical vapor deposition process, or a chemical vapor deposition process. As used herein, the term “chemical vapor deposition processes” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. As used herein, the term “thermal atomic layer deposition process” refers to atomic layer deposition process at substrate temperatures ranging from room temperature to 600° C. without in situ or remote plasma. Although the precursors, reagents and sources used herein may be sometimes described as “gaseous”, it is understood that the precursors can be either liquid or solid which are transported with or without an inert gas into the reactor via direct vaporization, bubbling or sublimation. In some case, the vaporized precursors can pass through a plasma generator.

In one embodiment, the silicon-containing film is deposited using an ALD process. In another embodiment, the silicon-containing film is deposited using a CCVD process. In a further embodiment, the silicon-containing film is deposited using a thermal ALD process. The term “reactor” as used herein, includes without limitation, reaction chamber or deposition chamber.

In certain embodiments, the method disclosed herein avoids pre-reaction of precursor(s) by using ALD or CCVD methods that separate the precursor(s) prior to and/or during the introduction to the reactor. In this connection, deposition techniques such as ALD or CCVD processes are used to deposit the silicon-containing film. In one embodiment, the film is deposited via an ALD process in a typical single wafer ALD reactor, semi-batch ALD reactor, or batch furnace ALD reactor by exposing the substrate surface alternatively to the one or more the silicon-containing precursor, oxygen source, nitrogen-containing source, or other precursor or reagent. Film growth proceeds by self-limiting control of surface reaction, the pulse length of each precursor or reagent, and the deposition temperature. However, once the surface of the substrate is saturated, the film growth ceases. In another embodiment, each reactant including the silicon precursor and reactive gas is exposed to a substrate by moving or rotating the substrate to different sections of the reactor and each section is separated by inert gas curtain, i.e. spatial ALD reactor or roll to roll ALD reactor.

Depending upon the deposition method, in certain embodiments, the silicon precursors described herein and optionally other silicon-containing precursors may be introduced into the reactor at a predetermined molar volume, or from about 0.1 to about 1000 micromoles. In this or other embodiments, the precursor may be introduced into the reactor for a predetermined time period. In certain embodiments, the time period ranges from about 0.001 to about 500 seconds.

In certain embodiments, the silicon-containing films deposited using the methods described herein are formed in the presence of a catalyst in combination with an oxygen source, reagent or precursor comprising oxygen, i.e. water vapors.

An oxygen source may be introduced into the reactor in the form of at least one oxygen source and/or may be present incidentally in the other precursors used in the deposition process. Suitable oxygen source gases may include, for example, water (H₂O) (e.g., deionized water, purified water, distilled water, water vapor, water vapor plasma, oxygenated water, air, a composition comprising water and other organic liquid), oxygen (O₂), oxygen plasma, ozone (O₃), nitric oxide (NO), nitrogen dioxide (NO₂), carbon monoxide (CO), a plasma comprising water, a plasma comprising water and argon, hydrogen peroxide, a composition comprising hydrogen, a composition comprising hydrogen and oxygen, carbon dioxide (CO₂), air, and combinations thereof. In certain embodiments, the oxygen source comprises an oxygen source gas that is introduced into the reactor at a flow rate ranging from about 1 to about 10000 square cubic centimeters (sccm) or from about 1 to about 1000 sccm. The oxygen source can be introduced for a time that ranges from about 0.1 to about 100 seconds. The catalyst is selected from a Lewis base such as pyridine, piperazine, trimethylamine, tert-butylamine, diethylamine, trimethylamine, ethylenediamine, ammonia, or other organic amines.

In embodiments wherein the film is deposited by an ALD or a cyclic CVD process, the precursor pulse can have a pulse duration that is greater than 0.01 seconds, and the oxygen source can have a pulse duration that is less than 0.01 seconds, while the water pulse duration can have a pulse duration that is less than 0.01 seconds.

In certain embodiments, the oxygen source is continuously flowing into the reactor while precursor pulse and plasma are introduced in sequence. The precursor pulse can have a pulse duration greater than 0.01 seconds while the plasma duration can range between 0.01 seconds to 100 seconds.

In certain embodiments, the silicon-containing films comprise silicon and nitrogen. In these embodiments, the silicon-containing films deposited using the methods described herein are formed in the presence of nitrogen-containing source. A nitrogen-containing source may be introduced into the reactor in the form of at least one nitrogen source and/or may be present incidentally in the other precursors used in the deposition process.

Suitable nitrogen-containing or nitrogen source gases may include, for example, ammonia, hydrazine, monoalkylhydrazine, symmetrical or unsymmetrical dialkylhydrazine, organoamines such as methylamine, ethylamine, ethylenediamine, ethanolamine, piperazine, N,N′-dimethylethylenediamine, imidazolidine, cyclotrimethylenetriamine, and combination thereof.

The deposition methods disclosed herein may involve one or more purge gases. The purge gas, which is used to purge away unconsumed reactants and/or reaction byproducts, is an inert gas that does not react with the precursors.

Exemplary purge gases include, but are not limited to, argon (Ar), nitrogen (N₂), helium (He), neon, hydrogen (H₂), and combinations thereof. In certain embodiments, a purge gas such as Ar is supplied into the reactor at a flow rate ranging from about 10 to about 10000 sccm for about 0.1 to 1000 seconds, thereby purging the unreacted material and any byproduct that may remain in the reactor.

The respective step of supplying the precursors, oxygen source, the nitrogen-containing source, and/or other precursors, source gases, and/or reagents may be performed by changing the time for supplying them to change the stoichiometric composition of the resulting film.

Energy is applied to the at least one of the precursor, nitrogen-containing source, reducing agent, other precursors or combination thereof to induce reaction and to form the film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof.

In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The silicon precursors and/or other silicon-containing precursors may be delivered to the reaction chamber, such as a CVD or ALD reactor, in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In this or other embodiments, it is understood that the steps of the methods described herein may be performed in a variety of orders, may be performed sequentially or concurrently (e.g., during at least a portion of another step), and any combination thereof. The respective step of supplying the precursors and the nitrogen-containing source gases may be performed by varying the duration of the time for supplying them to change the stoichiometric composition of the resulting silicon-containing film.

In a still further embodiment of the method described herein, the film or the as-deposited film is subjected to a treatment step. The treatment step can be conducted during at least a portion of the deposition step, after the deposition step, and combinations thereof. Exemplary treatment steps include, without limitation, treatment via high temperature thermal annealing; plasma treatment; ultraviolet (UV) light treatment; laser; electron beam treatment and combinations thereof to affect one or more properties of the film. The films deposited with the silicon precursors having one or two Si—C—C—Si linkages described herein, when compared to films deposited with previously disclosed silicon precursors under the same conditions, have improved properties such as, without limitation, a wet etch rate that is lower than the wet etch rate of the film before the treatment step or a density that is higher than the density prior to the treatment step. In one particular embodiment, during the deposition process, as-deposited films are intermittently treated. These intermittent or mid-deposition treatments can be performed, for example, after each ALD cycle, after a certain number of ALD, such as, without limitation, one (1) ALD cycle, two (2) ALD cycles, five (5) ALD cycles, or after every ten (10) or more ALD cycles.

In an embodiment wherein the film is treated with a high temperature annealing step, the annealing temperature is at least 100° C. or greater than the deposition temperature. In this or other embodiments, the annealing temperature ranges from about 400° C. to about 1000° C. In this or other embodiments, the annealing treatment can be conducted in a vacuum (<760 Torr), inert environment or in oxygen containing environment (such as H₂O, N₂O, NO₂ or O₂)

In an embodiment wherein the film is treated to UV treatment, film is exposed to broad band UV or, alternatively, an UV source having a wavelength ranging from about 150 nanometers (nm) to about 400 nm. In one particular embodiment, the as-deposited film is exposed to UV in a different chamber than the deposition chamber after a desired film thickness is reached.

In an embodiment wherein the film is treated with a plasma, passivation layer such as SiO₂ or carbon doped SiO₂ is deposited to prevent chlorine and nitrogen contamination from penetrating film in the subsequent plasma treatment.

The passivation layer can be deposited using atomic layer deposition or cyclic chemical vapor deposition.

In an embodiment wherein the film is treated with a plasma, the plasma source is selected from the group consisting of hydrogen plasma, plasma comprising hydrogen and helium, plasma comprising hydrogen and argon. Hydrogen plasma lowers film dielectric constant and boost the damage resistance to following plasma ashing process while still keeping the carbon content in the bulk almost unchanged.

Throughout the description, the term “ashing” refers to a process to remove the photoresist or carbon hard mask in semiconductor manufacturing process using a plasma comprising oxygen source such as O₂/inert gas plasma, O₂ plasma, CO₂ plasma, CO plasma, H₂/O₂ plasma or combination thereof.

Throughout the description, the term “damage resistance” refers to film properties after oxygen ashing process. Good or high damage resistance is defined as the following film properties after oxygen ashing: film dielectric constant lower than 4.5; carbon content in the bulk (at more than 50 Å deep into film) is within 5 at. % as before ashing; less than 50 Å of the film is damaged, observed by differences in dilute HF etch rate between films near surface (less than 50 Å deep) and bulk (more than 50 Å deep).

Throughout the description, the term “alkyl hydrocarbon” refers a linear or branched C₁ to C₂₀ hydrocarbon, cyclic C₆ to C₂₀ hydrocarbon. Exemplary hydrocarbon includes, but not limited to, heptane, octane, nonane, decane, dodecane, cyclooctane, cyclononane, cyclodecane.

Throughout the description, the term “aromatic hydrocarbon” refers a C₆ to C₂₀ aromatic hydrocarbon. Exemplary aromatic hydrocarbon n includes, but not limited to, toluene, mesitylene.

Throughout the description, the term “catalyst” refers a Lewis base in vapor phase which can catalyze surface reaction between hydroxyl group and Si—Cl bond during thermal ALD process. Exemplary catalysts include, but not limited to, at least one of a cyclic amine-based gas such as aminopyridine, picoline, lutidine, piperazine, piperidine, pyridine or an organic amine-based gas methylamine, dimethylamine, trimethylamine, ethylamine, diethylamine, triethylamine, propylamine, iso-propylamine, di-propylamine, di-iso-propylamine, tert-butylamine.

Throughout the description, the term “organic amines” refers a primary amine, secondary amine, tertiary amine having C₁ to C₂₀ hydrocarbon, cyclic C₆ to C₂₀ hydrocarbon. Exemplary organic amines include, but not limited to, methylamine, dimethylamine, trimethylamine, ethylamine, diethylamine, triethylamine, propylamine, iso-propylamine, di-propylamine, di-iso-propylamine, tert-butylamine.

Throughout the description, the term “siloxanes” refer a linear, branched, or cyclic liquid compound having at least one Si—O—Si linkages and C₄ to C₂₀ carbon atoms. Exemplary siloxanes includes, but are not limited to, tetramethyldisiloxane, hexamethyldisiloxane (HMDSO), 1,1,1,3,3,5,5,5-octarnethyltris:loxane, octamethylcyclotetrasiloxane (OMCTS).

Throughout the description, the term “step coverage” as used herein is defined as a percentage of two thicknesses of the deposited film in a structured or featured substrate having either vias or trenches or both, with bottom step coverage being the ratio (in %): thickness at the bottom of the feature is divided by thickness at the top of the feature, and middle step coverage being the ratio (in %): thickness on a sidewall of the feature is divided by thickness at the top of the feature. Films deposited using the method described herein exhibit a step coverage of about 80% or greater, or about 90% or greater which indicates that the films are conformal.

Throughout the description, the term “a film comprising silicon and oxygen” refers to carbon-doped silicon oxide film or carbon-doped silicon oxynitride film.

Throughout the description, the term “ALD or ALD-like” refers to a process including, but not limited to, the following processes: a) each reactant including silicon precursor and reactive gas is introduced sequentially into a reactor such as a single wafer ALD reactor, semi-batch ALD reactor, or batch furnace ALD reactor; b) each reactant including silicon precursor and reactive gas is exposed to a substrate by moving or rotating the substrate to different sections of the reactor and each section is separated by inert gas curtain, i.e. spatial ALD reactor or roll to roll ALD reactor.

The following examples illustrate certain aspects of the instant invention and do not limit the scope of the appended claims.

### EXAMPLES

### Example 1. Synthesis of 1,1-dichloro-3-trichlorosilyl-1-silacyclopentane

To 1,1-dichloro-1-silacyclopent-3-ene (19.8 g, 130 mmol) and trichlorosilane (21.9 g (162.0 mmol) in a 250 mL round bottom flask was added 0.10 mL Karstedt's catalyst in xylene (2% Pt by weight). The reaction turned yellow-brown and was heated at 80-90° C. for 4 hours. The resulting reaction mixture was subjected to fractional distillation (65° C./500 mTorr) to yield 32.1 g of the desired product as a colorless liquid determined to be 98% pure by GC-TCD analysis. GC-MS analysis of the product showed the following mass peaks: m/z=288 (M+), 262, 253, 225, 211, 187, 175, 153, 139, 135,127, 117, 115,99, 90, 63, 53.

### Example 2. Synthesis of 1,1-dichloro-3-(dichloromethylsilyl)silacyclopentane

A mixture of 1,1-dichloro-1-silacyclopent-3-ene (0.95 g, 0.01 mol) plus an equimolar quantity of MeHSiCl₂, was heated at 120° C. for 2 hours in Karstedt's catalyst (0.1 mL) presence in sealed stainless-steel tube. Analysis of the resulting mixture by GC-MS showed 1,1-dichloro-3-(dichloromethylsilyl)silacyclopentane as the major product. GC-MS showed the following peaks: m/z=268 (M), 253, 240, 125, 117, 105, 98, 90, 79, 63.

### Example 3. Synthesis of 1,1-dichloro-3-(chlorodimethylsilyl)silacyclopentane

A mixture of 1,1-dichloro-1-silacyclopent-3-ene (0.95 g, 0.01 mol) plus an equimolar quantity of MeHSiCl₂ was heated at 120° C. for 2 hours in Karstedt's catalyst (0.1 mL) presence in sealed stainless-steel tube. Analysis of the resulting mixture by GC-MS showed 1,1-dichloro-3-(chlorodimethylsilyl)silacyclopentane as the major product. GC-MS showed the following peaks: m/z=233 (M-15), 125, 117, 105, 93, 85, 78, 63.

### Example 4. Synthesis of 1,1-dichloro-3-(dichlorosilyl)silacyclopentane

7 Å mixture of 1,1-dichloro-1-silacyclopent-3-ene (0.95 g, 0.01 mol) plus an equimolar quantity of of H₂SiCl₂ was heated at 120° C. for 2 hours in Karstedt's catalyst (0.1 mL) presence in sealed stainless-steel tube. Analysis of the resulting mixture by GC-MS showed 1,1-dichloro-3-(dichlorosilyl)silacyclopentane as the major product. GC-MS showed the following peaks: m/z=220 (M-35), 1192, 153, 125, 117, 105, 99, 91, 83, 63.

### Example 5. Silicon-containing films deposition using thermal ALD process

Silicon-containing films were deposited at 300° C. and 550° C. by ALD methods using the following steps:

| Steps | Time | | | Details |
|---|---|---|---|---|
| Step 1 | | | Insert Si coupons into | Temperature set was 300° C. |
| | | | ALD reactor and heat | and 550° C. |
| | | | reactor to desired | |
| | | | temperature | |
| Step 2 | 25 | s | Pulse Si precursor | Throttle valve is closed |
| | | | and hold | Total precursor exposure = |
| | | | | 8 torr · s |
| Step 3 | 6 | s | Purge reaction by- | Nitrogen flow = 500 sccm |
| | | | products with nitrogen | Reactor pressure = 1.1 torr |
| Step 4 | 6 | s | Pump out nitrogen and | |
| | | | remaining gas from | |
| | | | the reactor | |
| Step 5 | 25 | s | Flow NH3 into reactor | Ammonia flow = 200 sccm |
| | | | | Reactor pressure = 5 torr |
| Step 6 | 6 | s | Purge reaction by- | Nitrogen flow = 500 sccm |
| | | | products with nitrogen | Reactor pressure = 1.1 torr |
| Step 7 | 6 | s | Pump out nitrogen and | |
| | | | remaining gas from | |
| | | | the reactor | |
| Step 8 | | | Remove Si coupons | Temperature < 100° C. |
| | | | from the tube | |

As shown in Tables IIa and IIb, the films were deposited at 300° C. and at 550° C. using the steps described above. The same method was performed using the precursor bis(trichlorosilyl)methane (BTCSM) and the films were compared. The film composition using the precursor 1,1-dichloro-3-trichlorosilyl-1-silacyclopentane had higher carbon than the film deposited using (BTCSM) at either temperature. The film compositions deposited using 1,1-dichloro-3-trichlorosilyl-1-silacyclopentane are shown below.

Table IIa Composition of silicon-containing film deposited using BTCSM.

| Deposition | | | | | |
|---|---|---|---|---|---|
| Temperature | Si | C | O | N | Cl |
| (° C.) | (at. %) | (at. %) | (at. %) | (at. %) | (at. %) |
| 300 | 27.7 | 11.9 | 57.9 | 2.4 | ND |

Table IIb Composition of silicon-containing films deposited using 1,1-dichloro-3-trichlorosilyl-1-silacyclopentane.

| Deposition | | | | | |
|---|---|---|---|---|---|
| Temperature | Si | C | O | N | Cl |
| (° C.) | (at. %) | (at. %) | (at. %) | (at. %) | (at. %) |
| 300 | 34.8 | 28.5 | 34.0 | 2.4 | 0.3 |
| 550 | 35.1 | 21.0 | 24.2 | 19.1 | 0.6 |

While the invention has been described with reference to certain embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1) A halidosilyl-substituted cyclic silicon precursor compound having at least 2 to 1 of carbon to silicon ratio according to Formula I: 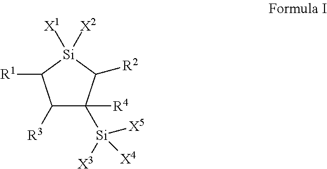
wherein R¹⁻⁴ are each independently selected from the group consisting of hydrogen, linear or branched or cyclic C₁ to C₁₀ alkyl, and halide, and wherein X¹⁻⁵ are independently selected from the group consisting of halide, hydrogen, and C₁ to C₁₀ alkyl with a proviso that at least one X¹⁻⁵ is halide.

2) The precursor compound of claim 1 wherein each of R¹⁻⁴ is independently selected from the group consisting of hydrogen or methyl, and each of X¹⁻⁵ is independently selected from the group consisting of hydrogen, methyl, Cl, Br and I.

3) The precursor compound of claim 1 selected from the group consisting of 1,1-dichloro-3-trichlorosilyl-1-silacyclopentane, 1,1-dichloro-3-dichlorosilyl-1-silacyclopentane, 1,1-dichloro-3-dichloromethylsilyl-1-silacyclopentane, 1,1-dichloro-3-dichloroethylsilyl-1-silacyclopentane, 1,1-dichloro-3-dichlorofluorosilyl-1-silacyclopentane, 1,1-dichloro-3-dichloroiodsilyl-1-silacyclopentane, 1,1-dichloro-3-chlorosilyl-1-silacyclopentane, and 1,1-dichloro-3-iodosilyl-1-silacyclopentane.

4) A composition including the precursor compound of claim 1 and further comprising a solvent, which comprises at least one member selected from the group consisting of ethers, tertiary amines, alkyl hydrocarbons, aromatic hydrocarbons, siloxanes, and tertiary aminoethers.

5) The composition of claim 4 wherein the difference between the boiling point of the precursor compound and the boiling point of the solvent is about 40° C. or less.

6) The composition of claim 4 where in the solvent comprises at least one member selected from the group consisting of heptane, octane, nonane, decane, dodecane, cyclooctane, cyclononane, cyclodecane, toluene, and mesitylene.

7) A method for forming a film comprising silicon and oxygen and having a carbon content ranging from 10 at. % to 50 at. % via a thermal ALD process, the method comprising:
a. placing one or more substrates comprising a surface feature into a reactor;
b. heating the reactor to one or more temperatures ranging from ambient temperature to about 600° C. and optionally maintaining the reactor at a pressure of 100 torr or less;
c. introducing into the reactor at least one silicon precursor comprising the precursor compound of claim 1;
d. purging the reactor with an inert gas;
e. providing a nitrogen source into the reactor to react with the surface to form a carbon doped silicon nitride film;
f. purging the reactor with an inert gas to remove reaction by-products;
g. repeating steps c to f to provide a desired thickness of the carbon doped silicon nitride film;
h. treating the resulting carbon doped silicon nitride film with an oxygen source at one or more temperatures ranging from about ambient temperature to 1000° C. or from about 100° C. to 400° C. to convert the carbon doped silicon nitride film into a carbon doped silicon oxide film; and
i. exposing the carbon doped silicon oxide film to a plasma comprising hydrogen.

8) The method of claim 7 wherein the precursor compound is selected from the group consisting of 1,1-dichloro-3-trichlorosilyl-1-silacyclopentane, 1,1-dichloro-3-dichlorosilyl-1-silacyclopentane, 1,1-dichloro-3-dichloromethylsilyl-1-silacyclopentane, 1,1-dichloro-3-dichloroethylsilyl-1-silacyclopentane, 1,1-dichloro-3-dichlorofluorosilyl-1-silacyclopentane, 1,1-dichloro-3-dichloroiodsilyl-1-silacyclopentane, 1,1-dichloro-3-chlorosilyl-1-silacyclopentane, and 1,1-dichloro-3-iodosilyl-1-silacyclopentane.

9) A film formed according to the method of claim 7 having a k of less than about 6.0, and a carbon content of at least about 15.0 at. %.

10) A stainless steel container housing the precursor compound of claim 1.

11) A method for forming a carbon doped silicon oxide film having carbon content ranging from 20 at % to 40 at. % via a thermal ALD process, the method comprising:
a. placing one or more substrates comprising a surface feature into a reactor;
b. heating the reactor to one or more temperatures ranging from ambient temperature to about 150° C. and optionally maintaining the reactor at a pressure of 100 torr or less;
c. introducing into the reactor at least one precursor comprising the precursor compound of claim 1 and a catalyst;
d. purging the reactor with an inert gas
e. providing vapors of water into the reactor to react with the at least one precursor as well as a catalyst to form a carbon doped silicon oxide film;
f. purging the reactor with an inert gas to remove reaction by-products; and
repeating steps c to f to provide a desired thickness of the carbon doped silicon oxide film.

12) The method of claim 11 further comprising treating the carbon doped silicon oxide film with a thermal anneal at temperatures from 500 to 1000° C.

13) The method of claim 11 further comprising exposing the carbon doped silicon oxide film to a plasma comprising hydrogen.

14) The method of claim 11 wherein the precursor compound is selected from the group consisting of 1,1-dichloro-3-trichlorosilyl-1-silacyclopentane, 1,1-dichloro-3-dichlorosilyl-1-silacyclopentane, 1,1-dichloro-3-dichloromethylsilyl-1-silacyclopentane, 1,1-dichloro-3-dichloroethylsilyl-1-silacyclopentane, 1,1-dichloro-3-dichlorofluorosilyl-1-silacyclopentane, 1,1-dichloro-3-dichloroiodsilyl-1-silacyclopentane, 1,1-dichloro-3-chlorosilyl-1-silacyclopentane, and 1,1-dichloro-3-iodorosilyl-1-silacyclopentane.
